(19) United States
(12) Patent Application Publication
(10) Pub. No.: US 2025/0309607 A1
(43) Pub. Date: Oct. 2, 2025

(54) SEMICONDUCTOR ELEMENT, METHOD FOR MANUFACTURING SEMICONDUCTOR ELEMENT, LIGHT-EMITTING DEVICE, AND METHOD FOR MANUFACTURING LIGHT-EMITTING DEVICE

(71) Applicant: NICHIA CORPORATION, Anan-shi (JP)

(72) Inventors: Hideyuki JOJIMA, Tokushima-shi (JP); Hirohito AIHARA, Tokushima-shi (JP)

(21) Appl. No.: 19/087,219

(22) Filed: Mar. 21, 2025

(30) Foreign Application Priority Data
Mar. 27, 2024 (JP) 2024-050649
Oct. 21, 2024 (JP) 2024-184946

(51) Int. Cl. H01S 5/02; H01S 5/02315

(52) U.S. Cl. CPC H01S 5/0202; H01S 5/02315

(57) ABSTRACT

A method for manufacturing a semiconductor element includes providing a layered body including a substrate having a crystal structure and a plurality of semiconductor layers layered on the substrate, and forming a groove having a shape with a branched tip in the layered body and dividing the layered body at the groove as a starting point.

### CROSS-REFERENCE TO RELATED APPLICATION

The present application claims priority under 35 U.S.C. § 119 to Japanese Patent Application No. 2024-050649, filed on Mar. 27, 2024, and Japanese Patent Application No. 2024-184946, filed on Oct. 21, 2024, the contents of which are hereby incorporated herein by reference in their entirety.

### BACKGROUND

### 1. Technical Field

The present disclosure relates to a semiconductor element, a method for manufacturing the semiconductor element, a light-emitting device, and a method for manufacturing the light-emitting device.

### 2. Description of Related Art

Japanese Patent Publication No. 2009-81428 discloses a method for producing individual elements by forming a division guide groove in a wafer including a group III nitride semiconductor substrate and dividing the wafer along the division guide groove.

### SUMMARY

The present disclosure provides a method for manufacturing a semiconductor element that can reduce the probability of cracking at a position away from a groove. The present disclosure also provides a semiconductor element in which the occurrence rate of abnormal appearance is reduced. The present disclosure also provides a manufacturing method that can reduce the probability of occurrence of cracks in a semiconductor element in a light-emitting device. The present disclosure also provides a light-emitting device including a semiconductor element in which the occurrence rate of cracks is reduced.

An aspect of a method for manufacturing a semiconductor element according to the present disclosure includes providing a layered body including a substrate having a crystal structure and a plurality of semiconductor layers layered on the substrate; and forming a groove having a shape with a branched tip in the layered body and dividing the layered body at the groove as a starting point.

An aspect of a semiconductor element according to the present disclosure includes a layered body including a lateral surface in a longitudinal direction, a lateral surface in a transverse direction, a first main surface, and a second main surface, wherein the lateral surface in the longitudinal direction includes a first region having a rough surface, a second region having a plurality of stripe-shaped steps extending from the first region toward the second main surface, and a plurality of recessed portions provided at a boundary between the first region and the second region.

An aspect of a method for manufacturing a light-emitting device according to the present disclosure includes producing a semiconductor element by the manufacturing method described above; and bonding the semiconductor element to a submount.

An aspect of a light-emitting device according to the present disclosure includes the semiconductor element described above; and a submount to which the semiconductor element is fixed.

According to the above-described method for manufacturing the semiconductor element, the probability of cracking at a position away from the groove can be reduced. In addition, the semiconductor element in which the occurrence rate of abnormal appearance is reduced can be produced. In addition, the probability of occurrence of cracks in the semiconductor element in the light-emitting device can be reduced. In addition, the light-emitting device including the semiconductor element in which the occurrence rate of cracks is reduced can be produced.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a flowchart illustrating a method for manufacturing a semiconductor element of an embodiment.

FIG. 2 is a schematic plan view illustrating a method for manufacturing a semiconductor element of an embodiment.

FIG. 3 is a cross-sectional view taken along line III-III of FIG. 2.

FIG. 4 is a schematic plan view illustrating a method for manufacturing a semiconductor element of an embodiment.

FIG. 5 is a schematic plan view illustrating a method for manufacturing a semiconductor element of an embodiment.

FIG. 6 is a cross-sectional view taken along line VI-VI of FIG. 5.

FIG. 7 is a partially enlarged view illustrating an example of the shape of a groove.

FIG. 8 is a schematic cross-sectional view illustrating a method for manufacturing a semiconductor element of an embodiment.

FIG. 9 is a schematic plan view illustrating a semiconductor element of an embodiment.

FIG. 10 is a cross-sectional view taken along line X-X of FIG. 9.

FIG. 11 is a schematic perspective view illustrating a semiconductor element of an embodiment.

FIG. 12 is a schematic view illustrating a lateral surface of a semiconductor element of an embodiment.

FIG. 13 is an optical microscope photograph of a groove in a method for manufacturing a semiconductor element of Example 2.

FIG. 14 is a scanning electron microscope (SEM) photograph of a lateral surface of a semiconductor element of Example 2.

FIG. 15 is a flowchart illustrating a method for manufacturing a light-emitting device of an embodiment.

FIG. 16 is a schematic cross-sectional view illustrating a light-emitting device of an embodiment.

### DETAILED DESCRIPTION OF EMBODIMENT

An embodiment of the present invention will be described below with reference to the drawings. In the drawings, the same elements are denoted by the same reference signs.

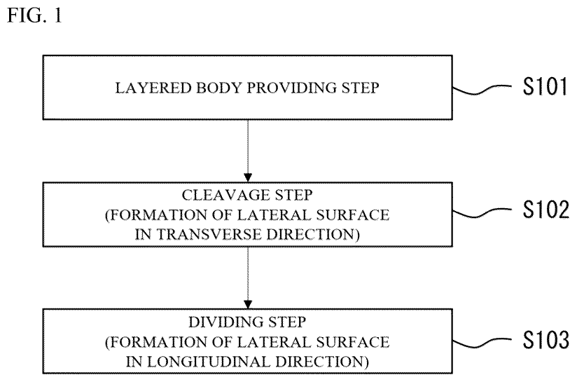

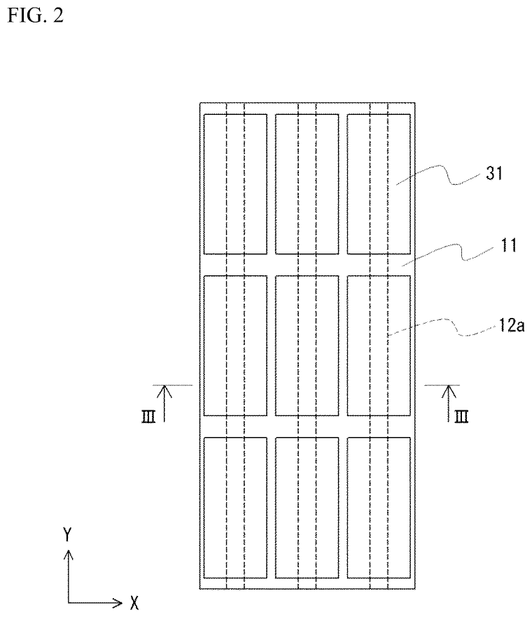

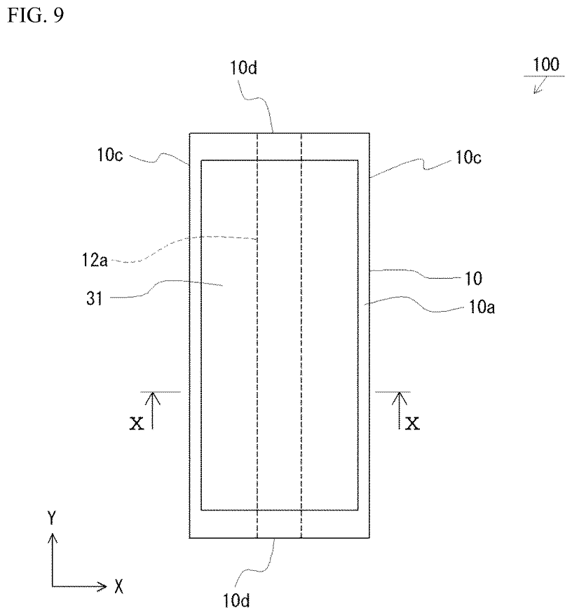

FIG. 1 is a flowchart illustrating a method for manufacturing a semiconductor element of the present embodiment. FIGS. 2 to 8 are schematic views for illustrating the method for manufacturing the semiconductor element according to the present embodiment. FIGS. 9 to 12 are schematic views for illustrating the semiconductor element according to the present embodiment.

As illustrated in FIG. 1, the method for manufacturing the semiconductor element of the present embodiment includes a layered body providing step S101 and a dividing step S103. In the layered body providing step S101, a layered body 10 including a substrate 11 having a crystal structure and a plurality of semiconductor layers 12 layered on the substrate 11 is provided. In the dividing step S103, a groove 20 having a shape with a branched tip is formed in the layered body 10, and the layered body 10 is divided at the groove 20 as a starting point. According to the method for manufacturing the semiconductor element of the present embodiment, the probability of cracking at a position away from the groove 20 can be reduced. The method for manufacturing the semiconductor element of the present embodiment may further include a cleavage step S102.

In a dividing method for dividing an object using a groove as a starting point, an increase in the depth of the groove facilitates division of the object. However, facilitation of division of the object increases the possibility that the object is cracked at an unintended timing such as when the object is being transported. In contrast, when the depth of the groove is reduced, cracking may occur at a position away from the groove. In a case in which the substrate 11 having a crystal structure is included as in the layered body 10 of the present embodiment, when the depth of the groove is too shallow, the substrate 11 may be cracked in an unintended direction due to the influence of the crystal structure of the substrate 11.

As a result of studies focusing on the shape of the groove 20, it has been found that when the layered body 10 including the substrate 11 having a crystal structure is divided, the probability of cracking at a position away from the groove 20 can be reduced by forming the groove 20 into a shape with a branched tip. This is probably due to the fact that when the tip of the groove 20 is branched, a crack can be extended from any position thereof, and thus the possibility of cracking at a position away from the groove 20 can be reduced. In other words, it is considered that the branched tip of the groove 20 increases an effective width in which the groove 20 can serve as a guide for division.

### Layered Body Providing Step S101

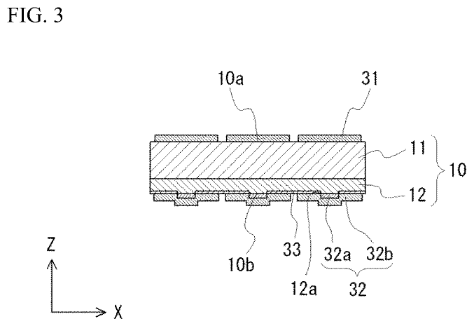

Firstly, the layered body providing step S101 is performed. In the layered body providing step S101, the layered body 10 is provided as illustrated in FIGS. 2 and 3. FIG. 2 is a schematic plan view illustrating the method for manufacturing the semiconductor element. FIG. 3 is a cross-sectional view taken along line III-III of FIG. 2. In each of the drawings, an X direction, a Y direction, and a Z direction are illustrated. The plan view is a view as seen along the Z direction. The X direction is a direction in which cleavage is performed in the cleavage step S102 described below. The Y direction is a direction in which division is performed in the dividing step S103 described below. The X direction, the Y direction, and the Z direction are orthogonal to one another.

The layered body 10 includes the substrate 11 having a crystal structure and the semiconductor layers 12 layered on the substrate 11. A ridge 12a may be formed on the semiconductor layers 12. The layered body 10 has a first main surface 10a and a second main surface 10b. The Z direction is a direction from the second main surface 10b toward the first main surface 10a. The ridge 12a may be formed on the second main surface 10b. The layered body 10 may be a wafer or may be a divided piece obtained by dividing the wafer into a plurality of portions.

The layered body 10 may have a thickness of, for example, 150 μm or less. The thickness of the layered body 10 may be 70 μm or less. This can reduce the drive voltage of a semiconductor element 100 to be produced. For example, when a first electrode 31 and a second electrode 32 are provided such that they sandwich the layered body 10 in the thickness direction of the layered body 10 as illustrated in FIG. 3, the resistance of a current path can be reduced by reducing the thickness of the layered body 10, and the drive voltage of the resultant semiconductor element 100 can be reduced. The thickness of the layered body 10 may be 30 μm or more. The thickness of the layered body 10 may be in a range from 30 μm to 100 μm, or may be in a range from 30 μm to 70 μm. The thickness of the layered body 10 is the distance from the second main surface 10b to the first main surface 10a in the Z direction. When the first main surface 10a and/or the second main surface 10b is not flat, the thickness of a portion having the maximum thickness is defined as the thickness of the layered body 10.

The substrate 11 preferably has an easy cleavage direction. Thus, at least one or more of the lateral surfaces of the semiconductor element 100 can be obtained by cleavage. Preferably, the easy cleavage direction of the substrate 11 coincides with a part of directions in which the lateral surfaces of the semiconductor element 100 are formed, but does not coincide with the other part of the directions. The groove 20 is formed in the non-coincident direction and the substrate 11 is divided, to thereby reduce the possibility that the substrate 11 is dragged in the easy cleavage direction of the substrate 11 and cracked at a position away from the groove 20 by the groove 20 whose effective width serving as a guide for division is substantially increased. When the produced semiconductor element 100 has a rectangular shape in plan view, the substrate 11 preferably has a hexagonal crystal structure. Examples of such a substrate 11 include a nitride semiconductor substrate having a wurtzite structure. Examples of the nitride semiconductor substrate include a group III nitride semiconductor substrate. Examples of the group III nitride semiconductor include GaN, InGaN, AlGaN, and AlN. For example, a GaN substrate can be used as the substrate 11. The easy cleavage plane of a nitride semiconductor having a wurtzite structure is an m-plane (i.e., {10-10} plane). In this case, one main surface of the substrate 11 is preferably a c-plane (i.e., a (0001) plane or a (000-1) plane). In the present disclosure, the c-plane is not limited to a plane strictly coinciding with the (0001) plane or the (000-1) plane, but also includes a plane having an off-angle in a range from ±0.03° to 1°.

The semiconductor layers 12 are each made of a semiconductor that can be formed on the substrate 11. The easy cleavage direction of the semiconductor constituting the semiconductor layers 12 preferably coincides with the easy cleavage direction of the substrate 11. Thus, the easy cleavage directions coincide with each other in the entire layered body 10, and the layered body 10 can be cleaved well. The semiconductor constituting the semiconductor layers 12 can be a nitride semiconductor, and may be a group III nitride semiconductor. Examples of the group III nitride semiconductor include GaN, InGaN, AlGaN, and AlN. The crystal orientations of the semiconductor layers 12 can be made substantially coincident with one another by epitaxially growing the semiconductor layers 12 on the surface of the substrate 11 composed of a group III nitride semiconductor. The semiconductor layers 12 can be formed by, for example, metal organic chemical vapor deposition (MOCVD). When the ridge 12a is formed on the semiconductor layers 12, for example, the ridge 12a can be formed by growing the semiconductor layers 12 and then removing a part of the semiconductor layers 12 by using photolithography and etching. The thickness of the semiconductor layers 12 may be smaller than the thickness of the substrate 11. The thickness of the semiconductor layers 12 can be 10 μm or less. The thickness of the semiconductor layers 12 can be 1 μm or more. The thickness of the semiconductor layers 12 is the distance from one main surface to the other main surface of the semiconductor layers 12 in the Z direction. When the main surfaces are not flat, the thickness of a portion having the maximum thickness is defined as the thickness of the semiconductor layers 12.

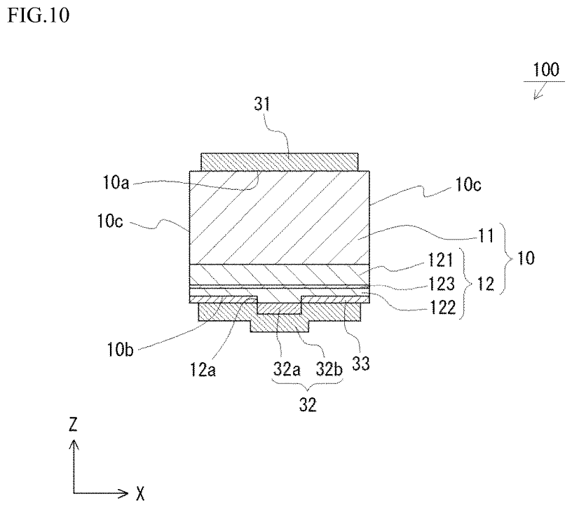

As illustrated in FIG. 10 described below, the semiconductor layers 12 can have a first conductive type semiconductor layer 121, a second conductive type semiconductor layer 122, and an active layer 123 interposed between the first conductive type semiconductor layer 121 and the second conductive type semiconductor layer 122. The semiconductor element 100 may be a semiconductor laser element. When the semiconductor element 100 is a semiconductor laser element, an optical waveguide can be defined by the ridge 12a. The ridge 12a has, for example, a stripe shape. The lateral surfaces crossing the ridge 12a serve as an end surface on a light-emitting side and an end surface on a light reflection side of the semiconductor element 100. The shape of the produced semiconductor element 100 in plan view may be a shape having a transverse direction and a longitudinal direction. The produced semiconductor element 100 can have one or more lateral surfaces in the transverse direction and one or more lateral surfaces in the longitudinal direction. When the shape of the semiconductor element 100 in plan view is a rectangle, the semiconductor element 100 has two lateral surfaces in the transverse direction and two lateral surfaces in the longitudinal direction. For example, one of the lateral surfaces in the transverse direction is set as the end surface on the light-emitting side. In this case, another one of the lateral surfaces in the transverse direction is set as the end surface on the light reflection side.

The layered body 10 can be provided with the first electrode 31 and the second electrode 32. Preferably, the first electrode 31 and the second electrode 32 do not overlap, in plan view, with a position to be cleaved in the cleavage step S102 and a position to be divided in the dividing step S103, which are described below. This can reduce the possibility that the first electrode 31 and the second electrode 32 adhere to a cleaved surface or a divided surface. One of the first electrode 31 and the second electrode 32 can be set as an n-electrode, and the other can be set as a p-electrode. In FIG. 3, the second electrode 32 includes a contact electrode 32a provided on the ridge 12a and a pad electrode 32b in contact with the contact electrode 32a.

Each of the first electrode 31 and the second electrode 32 can be formed by layering one or more layers of a metal such as Ni, Rh, Cr, Au, W, Pt, Ti, Al, or Pd or an alloy thereof. The first electrode 31 and the second electrode 32 may contain a conductive oxide. The contact electrode 32a may be a single-layer film or a multilayer film of a metal such as Ni, Rh, Cr, Au, W, Pt, Ti, or Al or an alloy thereof, a conductive oxide containing at least one metal selected from Zn, In, and Sn, or the like. Examples of the conductive oxide include indium tin oxide (ITO).

The layered body 10 may be provided with an insulating film 33. The insulating film 33 can be formed of, for example, a single-layer film or a multilayer film of an oxide or nitride of Si, Al, Zr, Ti, Nb, Ta, or the like.

### Cleavage Step S102

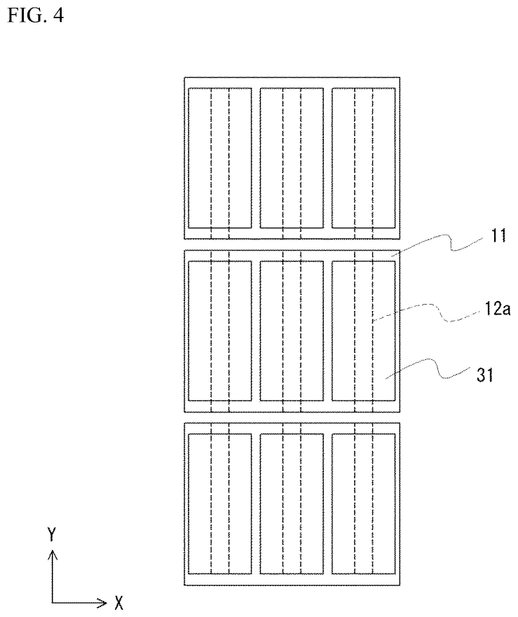

Subsequently, the cleavage step S102 can be performed. In the cleavage step S102, the layered body 10 is divided by cleavage. In the present embodiment, the layered body 10 is cleaved in the X direction in the drawing. This can result in the cleaved layered body 10 as illustrated in FIG. 4. FIG. 4 is a schematic plan view illustrating the method for manufacturing the semiconductor element 100. When the semiconductor element 100 is a semiconductor laser element, an end surface on a light-emitting side and an end surface on a light reflection side are preferably formed by cleavage, so that good end surfaces can be obtained.

The surface obtained in the cleavage step S102 may be a surface serving as a lateral surface of the semiconductor element 100 in the transverse direction. When the lateral surfaces of the semiconductor element 100 in the transverse direction are formed in the cleavage step S102, the layered body 10 is divided at a first interval in the cleavage step S102 and is divided at a second interval smaller than the first interval in the dividing step S103 described below.

The cleavage can be performed by, for example, first forming a groove in a part of a position to be cleaved and then pressing the layered body 10 with a blade. The groove can be formed using a laser scribing device, for example. The groove may be formed only outside a region to become the semiconductor element 100. For example, a groove can be formed at one end portion of a wafer or the layered body 10 being a divided piece obtained by dividing the wafer, and the layered body 10 can be cleaved along the groove by an external force.

When the substrate 11 is a substrate having a wurtzite structure, the cleavage direction preferably coincides with an m-plane in plan view. Thus, the cleavage can be performed with high accuracy. In the present disclosure, coinciding with the m-plane is not limited to strictly coinciding with the m-plane, and includes a case in which an angle with respect to the m-plane is 0.1° or less. Although the cleavage direction coincides with the X direction in the present embodiment, the cleavage direction may not coincide with the X direction.

When the semiconductor element 100 is a semiconductor laser element, a light-reflecting film or a protective film may be formed on the surface obtained by the cleavage after the cleavage step S102. When a film such as a light-reflecting film or a protective film is formed on a part of a plurality of lateral surfaces of the semiconductor element 100, division for forming a lateral surface on which the film is to be formed is preferably performed first, and then division in a different direction is preferably performed after formation of the film. This makes it easy to form a film on the lateral surface of the semiconductor element 100.

### Dividing Step S103

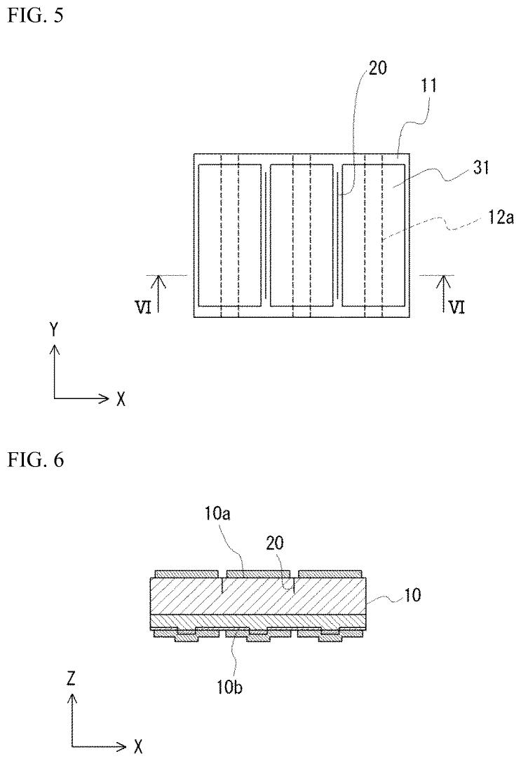

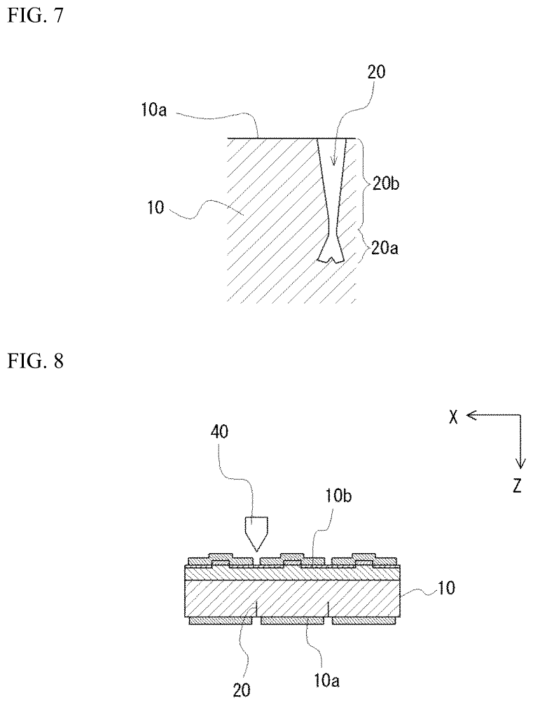

In the dividing step S103, as illustrated in FIGS. 5 to 8, the groove 20 having a shape with a branched tip is formed in the layered body 10, and the layered body 10 is divided at the groove 20 as a starting point. FIG. 5 is a schematic plan view illustrating the method for manufacturing the semiconductor element 100. FIG. 6 is a cross-sectional view taken along line VI-VI of FIG. 5. FIG. 7 is a partially enlarged view illustrating an example of the shape of the groove 20. FIG. 8 is a schematic cross-sectional view illustrating the method for manufacturing the semiconductor element 100. In the present embodiment, the layered body 10 is divided in the Y direction in the drawing. Although the dividing direction coincides with the Y direction in the present embodiment, the dividing direction may not coincide with the Y direction. When the dividing step S103 is performed after the cleavage step S102, the layered body 10 in which the groove 20 is formed is the layered body 10 after being cleaved in the cleavage step S102.

As illustrated in FIG. 7, the groove 20 has a shape with a branched tip. The groove 20 has a shape with a plurality of tips. Such a cross-sectional shape of the groove can be observed intermittently in a direction along the extending direction of the groove 20 (in the Y direction in the drawing). When the layered body 10 is light-transmissive, the shape of the groove can be observed from the lateral side of the layered body 10 by using an optical microscope. The shape of the groove may be observed in a cross section in a direction intersecting with the extending direction of the groove. The number of branches at the tip of the groove 20 is 2 or more. The number of branches at the tip of the groove 20 may be 10 or less, and may be 5 or less. The groove 20 can have a plurality of tip portions 20a each having a branched shape and being intermittently formed along the extending direction of the groove 20, and a connecting portion 20b connecting the tip portions 20a to the surface of the layered body 10. The ratio of the depth of the connecting portion 20b to the total depth of the groove 20 is preferably more than half. This makes it possible to divide the layered body 10 more stably. The depth of the groove 20 refers to the length of the layered body 10 in the direction from the second main surface 10b toward the first main surface 10a.

The ratio of the depth of the groove 20 to the thickness of the layered body 10 in the thickness direction of the layered body 10 can be 10% or more, and is preferably 20% or more. This enables better division. The ratio of the depth of the groove 20 to the thickness of the layered body 10 may be less than 50%, and is preferably 40% or less. This can further reduce the possibility of cracking at an unintended timing. The ratio of the depth of the groove 20 to the thickness of the layered body 10 may be in a range from 10% to less than 50%, and is preferably in a range from 10% to 40%. The ratio of the depth of the groove 20 to the thickness of the layered body 10 may be in a range from 20% to 40%.

The depth of the groove 20 can be 10 μm or more. The depth of the groove 20 is preferably 15 μm or more. This enables better division. The depth of the groove 20 can be 50 μm or less. This can further reduce the possibility of cracking at an unintended timing. The depth of the groove 20 may be 40 μm or less and may be 20 μm or less. When the thickness of the layered body 10 is 70 μm or less, the possibility of cracking at an unintended timing can be further reduced by setting the depth of the groove 20 to 20 μm or less. The depth of the groove 20 may be in a range from 10 μm to 50 μm, and is preferably in a range from 10 μm to 40 μm. The depth of the groove 20 may be in a range from 10 μm to 20 μm, and may be in a range from 10 μm to 15 μm.

The groove 20 preferably has a depth reaching the first main surface 10a but not reaching the second main surface 10b. In the dividing step S103, the groove 20 reaching the first main surface 10a but not reaching the second main surface 10b is formed, and the layered body 10 provided with the groove 20 is pressed from the second main surface 10b side, so that a crack is generated at the groove 20 as a starting point and the layered body 10 can be divided. When the layered body 10 is divided by pressing in this way, a phenomenon of cracking away from the groove 20 is likely to occur, but provision of the groove 20 can reduce the possibility of occurrence of such a phenomenon. For example, as illustrated in FIG. 8, the pressing is performed by pressing a pressing member 40 against the second main surface 10b directly or via a protective sheet. The pressing member 40 is, for example, a cutter or a blade. The pressing member 40 can be pressed immediately above the groove 20.

The first main surface 10a of the layered body 10 can be a surface of the substrate 11. The second main surface 10b of the layered body 10 can be a surface of the semiconductor layers 12. In this case, preferably, the groove 20 is provided only in the substrate 11 and is not provided in the semiconductor layers 12. This can further reduce the possibility of cracking at an unintended timing. The first main surface 10a may be the surface of the semiconductor layers 12, and the second main surface 10b may be the surface of the substrate 11. In this case, the groove 20 is preferably formed from the semiconductor layers 12 to a part of the substrate 11. Thus, the groove 20 having a sufficient depth can be formed and the division can be performed more satisfactorily.

The width of the groove 20 can be 50% or less of the depth of the groove 20, and may be 30% or less. The width of the groove 20 refers to a maximum length in a direction orthogonal to the extending direction of the groove 20. The width of the groove 20 can be, for example, 20 μm or less. The width of the groove 20 can be 1 μm or more, and may be 3 μm or more. The width of the groove 20 may be determined by observing the groove from the lateral side of the layered body 10 by using an optical microscope, or may be determined by observing a cross section in a direction intersecting with the extending direction of the groove 20. The groove 20 can also be observed from the side of the first main surface 10a by using an optical microscope. The maximum value of the width of the groove 20 in such plan view may be 50 μm or less, or may be 30 μm or less.

The groove 20 may not be formed over the entire length to be divided in the dividing step S103. In FIG. 5, the groove 20 is formed in a part of the length to be divided in the dividing step S103. The groove 20 is provided such that it does not reach the cleaved surface, thereby reducing the possibility that debris generated during formation of the groove 20 adheres to the cleaved surface.

The direction in which the layered body 10 is divided is preferably different from the easy cleavage direction of the substrate 11. When the layered body 10 is divided in a direction different from the easy cleavage direction, a phenomenon of cracking away from the groove 20 is likely to occur, but provision of the groove 20 can reduce the possibility of occurrence of such a phenomenon.

The dividing step S103 may be a step of forming the lateral surfaces of the semiconductor element 100 in the longitudinal direction. The length of the lateral surface of the semiconductor element 100 formed in the dividing step S103 is preferably 1 mm or more. The length of the lateral surface of the semiconductor element 100 refers to the length in the direction along the dividing direction. When the division distance is longer, cracking away from the groove 20 is likely to occur. However, provision of the groove 20 can reduce the possibility of cracking away from the groove 20. In addition, as the length of the lateral surface of the semiconductor element 100 is increased, the optical output of the semiconductor element 100 can be increased. The length of the lateral surface of the semiconductor element 100 formed in the dividing step S103 may be 10 mm or less or may be 5 mm or less.

When the thickness of the layered body 10 is 70 μm or less, the length of the lateral surface of the semiconductor element 100 is preferably 5 mm or less. This makes it possible to ensure the strength of the semiconductor element 100, although the strength of the semiconductor element 100 tends to decrease as the thickness of the layered body 10 decreases. In this case, the length of the lateral surface of the semiconductor element 100 may be in a range from 1 mm to 5 mm, may be in a range from 1 mm to 3 mm, or may be in a range from 1 mm to 2 mm. The thickness of the layered body 10 may exceed 70 μm. In this case, the length of the lateral surface of the semiconductor element 100 may be in a range from 1 mm to 10 mm, may be in a range from 3 mm to 10 mm, or may be in a range from 4 mm to 10 mm.

The groove 20 can be formed by laser processing. The groove 20 can be formed by laser processing using a pulsed laser beam. The groove 20 can be formed using a laser scribing device. The groove 20 having a shape with a branched tip can be formed by changing laser processing conditions from those for forming a V-shaped groove toward laser processing conditions in which a repetition frequency is increased and peak output is decreased. The laser processing conditions for forming the V-shaped groove are conditions under which ablation processing is performed. It is considered that when these conditions are adjusted toward conditions in which the repetition frequency is increased and the peak output is decreased, the influence of thermal processing is increased at the tip although the thermal processing is mainly the ablation processing. Therefore, it is considered that the groove 20 having a shape with a branched tip can be formed.

The conditions under which a groove can be formed in the layered body 10 mainly by ablation processing are selected as the laser processing conditions for forming the groove 20. When a GaN substrate is used as the substrate 11, for example, a nanosecond UV laser can be used. The laser processing conditions can be adjusted, for example, in a range of a pulse width of nanoseconds or picoseconds, a repetition frequency of 40 kHz to 200 kHz, an average output of 0.5 W to 10 W, and a condensing diameter at a condensing position of 2 μm to 20 μm. Since the depth of the groove 20 formed can be changed by increasing or decreasing the repetition frequency, the depth of the groove 20 may be adjusted by adjusting a scanning speed. The scanning speed can be adjusted in a range of, for example, 5 mm/s to 500 mm/s. The laser processing conditions for forming the groove 20 may be conditions in which the average output of a laser beam is the same, the repetition frequency is higher, and the peak output is lower as compared with the laser processing conditions for forming the V-shaped groove.

Through the above-described steps, the semiconductor element 100 can be produced.

### Semiconductor Element 100

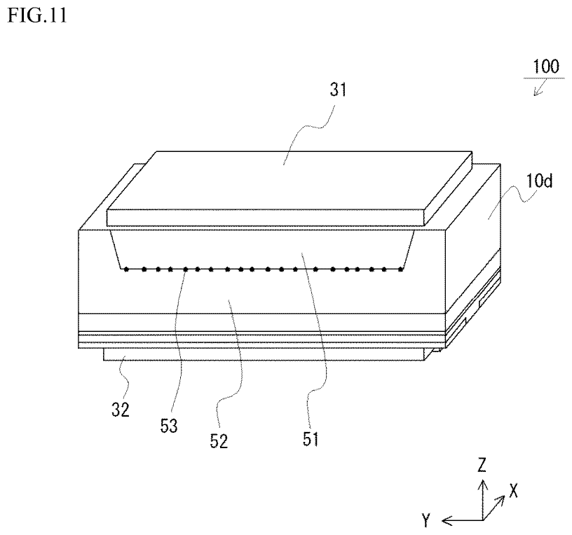

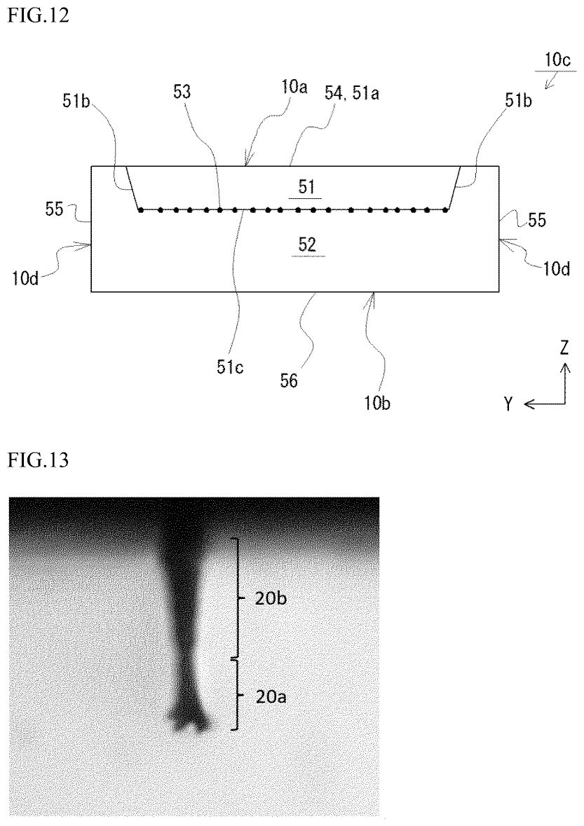

FIGS. 9 to 12 illustrate the semiconductor element 100 of the present embodiment. FIG. 9 is a schematic plan view illustrating the semiconductor element 100. FIG. 10 is a cross-sectional view taken along line X-X of FIG. 9. FIG. 11 is a schematic perspective view illustrating the semiconductor element 100. FIG. 12 is a schematic view illustrating the lateral surface of the semiconductor element 100.

The semiconductor element 100 includes the layered body 10 having a lateral surface 10c in the longitudinal direction, a lateral surface 10d in the transverse direction, the first main surface 10a, and the second main surface 10b. The lateral surface 10c in the longitudinal direction has a first region 51 including a rough surface and a second region 52 including a plurality of stripe-shaped steps extending from the first region 51 toward the second main surface 10b. A plurality of recessed portions 53 are provided at a boundary between the first region 51 and the second region 52.

The first region 51 and the recessed portions 53 are considered to be portions that have been the grooves 20. It is considered that the branched portions at the tip of the groove 20 have remained as the recessed portions 53. In this way, the tip shape of the groove 20 may remain as a trace. Each of the recessed portions 53 is a portion recessed toward the inside of the layered body 10. The second region 52 is considered to be a portion cracked by a crack extending from the groove 20. In the second region 52, a plurality of stripe-shaped traces extending from the first region 51 toward the second main surface 10b are confirmed as the traces of cracks. Most of the stripe-shaped steps (stripe-shaped traces) are linear. The first region 51 has a random rough surface as compared with the second region 52. The first region 51 has protrusions and recessions having a size smaller than the length of the stripe-shaped step of the second region 52. Such a state of the lateral surface may be observed with an optical microscope or a scanning electron microscope (SEM). The recessed portions 53 can be confirmed by an SEM photograph.

The layered body 10 has at least one lateral surface 10c in the longitudinal direction and at least one lateral surface 10d in the transverse direction. In the present embodiment, the layered body 10 has two lateral surfaces 10c in the longitudinal direction and two lateral surfaces 10d in the transverse direction.

The lateral surface 10c in the longitudinal direction has a first side 54 meeting the first main surface 10a, a second side 55 meeting the lateral surface 10d in the transverse direction, and a third side 56 meeting the second main surface 10b. The first region 51 has a first boundary 51a coinciding with the first side 54, a second boundary 51b spaced apart from the second side 55 and facing the second side 55, and a third boundary 51c spaced apart from the third side 56 and facing the third side 56. The recessed portions 53 are provided at the third boundary 51c. The first region 51 can have an inverted trapezoidal shape in which the first boundary 51a is longer than the third boundary 51c.

The recessed portions 53 are distributed over the entire third boundary 51c. The number of the recessed portions 53 tends to be smaller than the number of laser processing operations when the groove 20 is formed. In at least five different points on the lateral surface 10c in the longitudinal direction, the number of the recessed portions 53 in a width of 20 μm may be four or more. In the SEM photograph, the recessed portions 53 are observed as portions closer to black than the first region 51 and the second region 52. A secondary electron (SE) image at a magnification of 2500 times and an acceleration voltage of 5 kV can be used as the SEM photograph. The number of the recessed portions 53 in a region having the width of 20 μm may be four or more, or may be seven or more in each observation region. The number of the recessed portions 53 in a region having the width of 20 μm may be 15 or less, or may be 11 or less in each observation region. The interval between the recessed portions 53 may be in a range from 0.5 μm to 10 μm. The length of the recessed portion 53 in the thickness direction of the layered body 10 may be 2 μm or less.

The length of the first region 51 in the thickness direction of the layered body 10 can be in the same range as the depth of the groove 20 described above. In the present embodiment, the surface on which the trace of the groove 20 remains is the lateral surface 10c in the longitudinal direction. However, depending on the shape of the semiconductor element 100, a lateral surface other than the lateral surface 10c in the longitudinal direction may be the surface on which the trace of the groove 20 remains.

The semiconductor layers 12 can include the first conductive type semiconductor layer 121, the second conductive type semiconductor layer 122, and the active layer 123 interposed between the first conductive type semiconductor layer 121 and the second conductive type semiconductor layer 122. The first conductive type semiconductor layer 121 is, for example, an n-type semiconductor layer. The second conductive type semiconductor layer 122 is, for example, a p-type semiconductor layer. The substrate 11, the first conductive type semiconductor layer 121, the active layer 123, and the second conductive type semiconductor layer 122 may be in direct contact with one another, or another semiconductor layer may be disposed therebetween. For example, an undoped layer may be disposed between the second conductive type semiconductor layer 122 and the active layer 123. The active layer 123 can have a multiple quantum well structure or a single quantum well structure. For example, the semiconductor layers 12 include, in order from the substrate 11 side, an n-side cladding layer, an n-side optical guide layer, the active layer 123, a p-side electron confinement layer, a p-side optical guide layer, a p-side cladding layer, and a p-side contact layer. For example, the n-side cladding layer is the first conductive type semiconductor layer 121, and the p-side cladding layer is the second conductive type semiconductor layer 122.

The semiconductor element 100 can include the first electrode 31 and the second electrode 32. The semiconductor element 100 may have the insulating film 33. When the semiconductor element 100 is a semiconductor laser element, the semiconductor element 100 may have a light-reflecting film or a protective film provided on the lateral surface 10d in the transverse direction. The length of the semiconductor element 100 in the longitudinal direction may be equal to or greater than twice the length in the transverse direction. The length of the semiconductor element 100 in the longitudinal direction may be equal to or less than 50 times the length in the transverse direction.

### Light-Emitting Device and Manufacturing Method Therefor

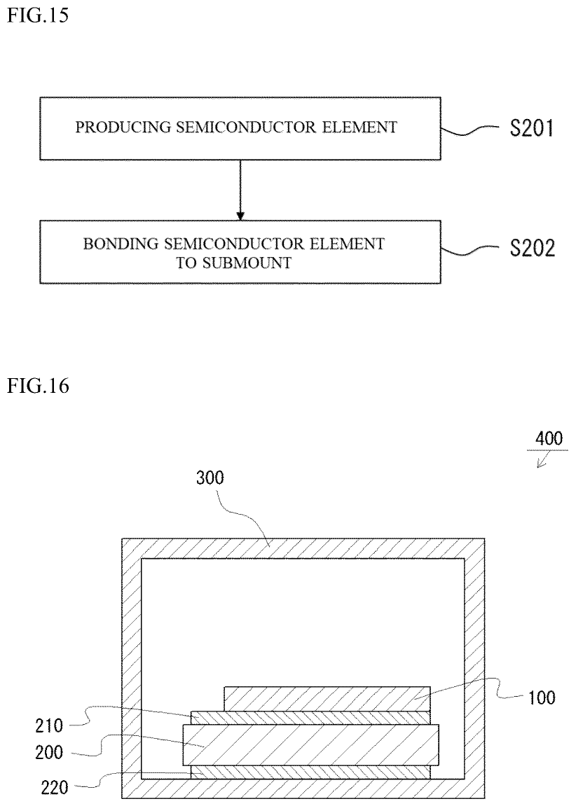

FIG. 15 is a flowchart illustrating a method for manufacturing the light-emitting device of the present embodiment. FIG. 16 is a schematic cross-sectional view illustrating the light-emitting device of the present embodiment.

As illustrated in FIG. 15, a method for manufacturing a light-emitting device 400 of the present embodiment includes a step S201 of producing the semiconductor element 100 and a step S202 of bonding the semiconductor element 100 to a submount. In the step S201 of producing the semiconductor element 100, the above-described method for manufacturing the semiconductor element 100 is used. This can reduce the probability of occurrence of cracks in the semiconductor element 100 in the light-emitting device 400.

The light-emitting device 400 includes the semiconductor element 100 and a submount 200 to which the semiconductor element 100 is fixed. This can produce the light-emitting device 400 including the semiconductor element 100 in which the occurrence rate of cracks is reduced. The light-emitting device 400 can include a first metal film 210 provided on an upper surface of the submount 200 and a second metal film 220 provided on a lower surface of the submount 200. The light-emitting device 400 may have only one of the first metal film 210 and the second metal film 220. The light-emitting device 400 can include a housing 300.

Even in the case of a semiconductor element in which an abnormal crack or an appearance defect is not confirmed in a preliminary appearance evaluation, a crack may be confirmed in the semiconductor element when the semiconductor element is observed after being fixed to a submount or after being driven. Since such a crack extends from a trace of a groove used for division in the dividing step, it is considered that a minute crack (microcrack) may occur in association with the processing of the groove. There is a possibility that after formation of the groove, a load causing the microcrack to extend is applied to the semiconductor element, so that the microcrack extends and develops into a crack. Examples of factors that generate a load causing a microcrack to extend include a load at the time of dividing the layered body, heat generation or heating of the semiconductor element, and application of stress due to a difference in thermal expansion coefficient between the semiconductor element and a submount to which the semiconductor element is fixed.

The groove 20 having a shape with a branched tip is formed in the layered body 10 and the layered body 10 is divided at the groove 20 as a starting point, to thereby reduce the probability that a crack is confirmed after the layered body 10 is fixed to the submount. It is considered that this is because a load at the time of dividing the layered body is reduced by dividing the layered body at the groove 20 having such a shape as a starting point. It is considered that the extension of the microcrack can be suppressed by reducing this load. Thus, the probability of occurrence of cracking can be reduced.

The length of the lateral surface of the semiconductor element 100 is preferably 1 mm or more, more preferably 3 mm or more. The length of the lateral surface of the semiconductor element 100 may be 4 mm or more. As the length of the lateral surface of the semiconductor element 100 is increased, the optical output of the semiconductor element 100 can be increased. As the optical output increases, the amount of generated heat tends to increase. However, provision of the groove 20 can reduce the probability of occurrence of cracks in the semiconductor element 100.

A bonding material may be used to bond the submount 200 and the semiconductor element 100. The first metal film 210 may contain a bonding material. Examples of the bonding material include an inorganic bonding material. Thus, when the semiconductor element 100 is a semiconductor laser element, the possibility of occurrence of dust collection can be reduced. Examples of the inorganic bonding material include a bonding material made of only a metal, such as AuSn. The inorganic bonding material may be formed by using a paste containing metal particles and an organic binder and volatilizing the organic binder by heating.

Heat of the semiconductor element 100 can be dissipated to the housing 300 and the outside thereof via the submount 200. Therefore, the submount 200 is preferably made of a material having high thermal conductivity. The submount 200 is preferably a diamond submount. This can improve the heat dissipation performance of the submount 200. When the submount 200 is a diamond submount, the difference in thermal expansion coefficient between the submount 200 and the semiconductor element 100 is relatively large. However, the probability of occurrence of cracks in the semiconductor element 100 can be reduced by providing the groove 20. The thickness of the submount 200 is, for example, 0.3 mm.

Each of the first metal film 210 and the second metal film 220 can contain, for example, at least one metal selected from the group consisting of Ti, Pt, Cu, and Au. The first metal film 210 and the second metal film 220 are each made of, for example, Cu. The thickness of the first metal film 210 is, for example, 50 μm. The thickness of the second metal film 220 is, for example, 50 μm. A single-layer or multilayer metal layer may be provided on a lower surface and/or an upper surface of the first metal film 210. A single-layer or multilayer metal layer may be provided on a lower surface and/or an upper surface of the second metal film 220.

The housing 300 seals the semiconductor element 100 and the submount 200. The housing 300 can hermetically seal the semiconductor element 100 and the submount 200. Thus, when the semiconductor element 100 is a semiconductor laser element, the possibility of occurrence of dust collection can be reduced. The housing 300 can contain a metal, a ceramic, or a composite thereof. When the semiconductor element 100 is a light-emitting element, the housing 300 has a light-transmitting portion for extracting light emitted by the light-emitting element to the outside. The light-transmitting portion can be made of glass or sapphire. The light-emitting device 400 may further include a reflective member that reflects light emitted by the light-emitting element.

### Examples 1 to 5

Semiconductor laser elements each having a longitudinal direction and a transverse direction in plan view were produced as semiconductor elements of Examples 1 to 5. Firstly, a layered body made of a group III nitride semiconductor was provided as a layered body. A GaN substrate was used as the substrate. The thickness of the layered body was about 60 μm. Subsequently, the layered body was cleaved to form a plane serving as a lateral surface in the transverse direction. Subsequently, a groove was formed in the layered body by laser processing, and the layered body was divided at the groove as a starting point to form a lateral surface in the longitudinal direction. The groove was formed on a side of a first main surface of the layered body, and then a side of a second main surface of the layered body was pressed by a pressing member. The length of the semiconductor element 100 in the longitudinal direction was 1.2 mm. The groove was formed using a nanosecond laser with a central wavelength of 355 nm. The average output of the laser processing using the nanosecond laser was 1W, and the depth of the groove and the repetition frequency were as shown in Table 1.

### Comparative Example and Referential Example

As semiconductor elements of Comparative Example and Referential Example, semiconductor laser elements were produced in the same manner as in Example 1 except for the repetition frequency shown in Table 1.

TABLE 1

| | Groove | | | | |
|---|---|---|---|---|---|
| | depth | Frequency | Tip | Abnormal | Appearance |
| | [μm] | [Hz] | branching | crack | defect |
| Example 1 | 18 | 120 | Presence | Absence | Less |
| | | | | | than 1% |
| Example 2 | 18 | 140 | Presence | Absence | Less |
| | | | | | than 1% |
| Example 3 | 18 | 160 | Presence | Absence | Less |
| | | | | | than 1% |
| Example 4 | 18 | 180 | Presence | Absence | Less |
| | | | | | than 1% |
| Example 5 | 35 | 70 | Presence | Absence | Slightly |
| | | | | | more |
| Comparative | 18 | 70 | Absence | Many | Many |
| Example | | | | | |
| Referential | 18 | 100 | Absence | Slightly | Slightly |
| Example | | | | more | more |

### Evaluation of Shape of Groove

In the course of producing the semiconductor element of each of the Examples, the Comparative Example, and the Referential Example, the shape of the groove was observed after formation of the groove and before pressing and dividing. An optical microscope was used to focus on the groove from the lateral surface of the layered body to photograph the groove, and the shape of the groove was determined from the image. The results are shown in Table 1. As shown in Table 1, in Examples 1 to 5, the groove had a shape having a tip with two or more branches. FIG. 13 illustrates an optical microscope photograph of the groove in Example 2. In the Comparative Example and the Referential Example, the groove was V-shaped, and branching of the tip was not confirmed.

### Appearance Evaluation

A plurality of semiconductor elements were produced in each of the Examples, the Comparative Example, and the Referential Example, and subjected to appearance evaluation. The appearance evaluation was performed from the viewpoint of an abnormal crack and an appearance defect, and the occurrence rate of each of them was evaluated. The abnormal crack was determined based on the presence or absence of a crack away from the groove and reaching the first electrode of the semiconductor element, and the appearance defect was determined based on whether the shortest distance between the side of the semiconductor element in the longitudinal direction and the first electrode in plan view was less than a predetermined distance although no abnormal crack was observed. The results are shown in Table 1. An abnormal crack occurred in the Comparative Example and the Referential Example, but the occurrence of an abnormal crack was not observed in Examples 1 to 5. The appearance defect occurred less frequently in all of Examples 1 to 5 than in the Comparative Example. In Examples 1 to 4, the occurrence frequency of an appearance defect was less than 1%, which was lower than the occurrence frequencies in both the Comparative Example and the Referential Example.

### Observation of Lateral Surface

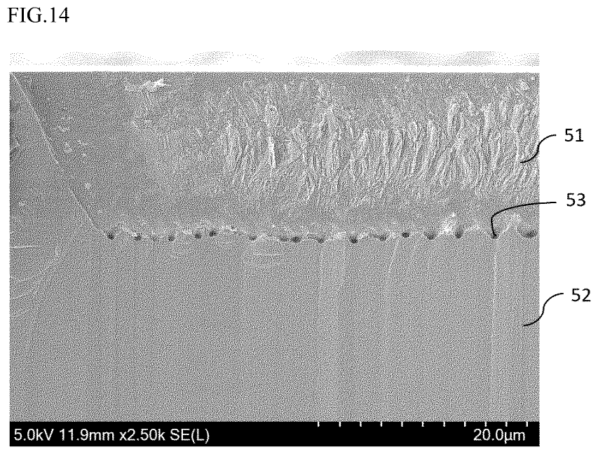

The semiconductor element of each of the Examples, the Comparative Example, and the Referential Example was observed with an optical microscope. As a result, the semiconductor element was found to have a first region including a rough surface seeming to be a trace of a groove and a second region including a plurality of stripe-shaped steps extending from the first region toward the second main surface. An SEM photograph of the lateral surface in the longitudinal direction was taken for each of the semiconductor elements of Example 2, Example 5, and the Comparative Example. A secondary electron (SE) image at a magnification of 2500 times and an accelerating voltage of 5 kV was used as the SEM photograph. The SEM photograph was used to count the number of recessed portions located at the boundary between the first region and the second region at five different points in a region having a width of 20 μm in the longitudinal direction of the semiconductor element. The results are shown in Table 2. Determination points A to E in Table 2 are points used for determining the number of recessed portions. The determination point A in Example 2, the determination point A in Example 5, and the determination point A in the Comparative Example each mean the first determination point, and are not necessarily located at the same position. Similarly, the determination points B to E are not necessarily located at the same position. As shown in Table 2, no recessed portion was observed in the Comparative Example in which the V-shaped groove was formed. In each of Example 2 and Example 5, in which a groove having a shape with a branched tip was formed, a plurality of recessed portions were confirmed in each region. FIG. 14 illustrates an SEM photograph of a lateral surface in the longitudinal direction of the semiconductor element of Example 2. In the SEM photograph, a recessed portion corresponds to a substantially circular portion located at the boundary between the first region and the second region and closer to black than those regions. These recessed portions are considered to be the remaining branched portions at the tip of the groove.

TABLE 2

| | Number of recessed portions | | | | |
|---|---|---|---|---|---|
| | Determination | Determination | Determination | Determination | Determination |
| | point A | point B | point C | point D | point E |
| Example 2 | 8 | 11 | 7 | 8 | 7 |
| Example 5 | 7 | 8 | 5 | 6 | 4 |
| Com- | 0 | 0 | 0 | 0 | 0 |
| parative | | | | | |
| Example | | | | | |

What is claimed is:

1. A method for manufacturing a semiconductor element, the method comprising:
providing a layered body including a substrate having a crystal structure and a plurality of semiconductor layers layered on the substrate; and
forming a groove having a shape with a branched tip in the layered body and dividing the layered body at the groove as a starting point.

2. The method for manufacturing a semiconductor element according to claim 1, wherein
the providing of the layered body includes providing the layered body having a first main surface and a second main surface, and
the dividing of the layered body includes forming the groove so that the groove reaches the first main surface and the groove does not reach the second main surface, and pressing the layered body from a side of the second main surface to generate a crack at the groove as the starting point to divide the layered body.

3. The method for manufacturing a semiconductor element according to claim 1, wherein
the dividing of the layered body includes dividing the layered body along a direction different from an easy cleavage direction of the crystal structure of the substrate.

4. The method for manufacturing a semiconductor element according to claim 1, wherein
the semiconductor element has, in plan view, a shape with a side extending along a transverse direction and a side extending along a longitudinal direction, and
the dividing of the layered body includes dividing the layered body to form a lateral surface of the semiconductor element in the longitudinal direction.

5. The method for manufacturing a semiconductor element according to claim 4, further comprising
dividing the layered body by cleavage to form a lateral surface of the semiconductor element in the transverse direction.

6. The method for manufacturing a semiconductor element according to claim 1, wherein
the semiconductor layers includes a first conductive type semiconductor layer, a second conductive type semiconductor layer, and an active layer interposed between the first conductive type semiconductor layer and the second conductive type semiconductor layer, and
the semiconductor element is a semiconductor laser element.

7. The method for manufacturing a semiconductor element according to claim 1, wherein
the dividing of the layered body includes dividing the layered body to form a lateral surface of the semiconductor element having a length of 1 mm or more.

8. The method for manufacturing a semiconductor element according to claim 1, wherein
the providing of the layered body includes providing the layered body having a thickness of 70 μm or less.

9. A method for manufacturing a light-emitting device, the method comprising:
producing a semiconductor element by the method of manufacturing a semiconductor element according to claim 1; and
bonding the semiconductor element to a submount.

10. The method for manufacturing a light-emitting device according to claim 9, wherein
the submount is a diamond submount.

11. A semiconductor element comprising:
a layered body having a lateral surface in a longitudinal direction, a lateral surface in a transverse direction, a first main surface, and a second main surface, wherein
the lateral surface in the longitudinal direction has
a first region with a rough surface,
a second region with a plurality of stripe-shaped steps extending from the first region toward the second main surface, and
a plurality of recessed portions arranged at a boundary between the first region and the second region.

12. The semiconductor element according to claim 11, wherein
the lateral surface in the longitudinal direction has a first side meeting the first main surface, a second side meeting the lateral surface in the transverse direction, and a third side meeting the second main surface,
the first region has a first boundary coinciding with the first side, a second boundary spaced apart from the second side and facing the second side, and a third boundary spaced apart from the third side and facing the third side, and
the recessed portions are provided at the third boundary.

13. The semiconductor element according to claim 11, wherein
in at least five different points on the lateral surface in the longitudinal direction, a number of the recessed portions in a region having a width of 20 μm in the longitudinal direction is four or more.

14. The semiconductor element according to claim 11, wherein
the lateral surface in the longitudinal direction has a length of 3 mm or more.

15. A light-emitting device comprising:
the semiconductor element according to claim 11; and
a diamond submount to which the semiconductor element is fixed.
